(19) United States
(12) Patent Application Publication
(10) Pub. No.: US 2026/0066213 A1
(43) Pub. Date: Mar. 5, 2026

(54) METHODS AND APPARATUS FOR ADAPTIVE CHARGE NEUTRALIZATION USING AN ANTENNA MOUNTED TO AN ION EMITTER

(71) Applicant: Illinois Tool Works Inc., Glenview, IL (US)

(72) Inventors: Steven Bernard Heymann, Los Gatos, CA (US); Aleksey Klochkov, San Francisco, CA (US); Edward Anthony Oldynski, Martinez, CA (US); Juan Guerrero, Berkeley, CA (US); Joseph Cassio, Oakland, CA (US)

(21) Appl. No.: 19/308,783

(22) Filed: Aug. 25, 2025

Related U.S. Application Data
(60) Provisional application No. 63/689,209, filed on Aug. 30, 2024.

(51) Int. Cl. H01J 37/08; H01J 37/244

(52) U.S. Cl. CPC H01J 37/08; H01J 37/244; H01J 2237/0041; H01J 2237/2487

(57) ABSTRACT

Disclosed example ion emitters include: a body; a plurality of emitter nozzles on the body; a power supply configured to supply a high frequency alternating current (AC) signal to the plurality of emitter nozzles; an antenna configured to measure an ion balance of ions emitted by the plurality of emitter nozzles; control circuitry configured to control the power supply based on the ion balance measured via the antenna; and an antenna hanger supported by the body and configured to position the antenna within an emission path of the plurality of emitter nozzles.

### RELATED APPLICATIONS

The present application claims the benefit of U.S. Provisional Patent Application Ser. No. 63/689,209, filed Aug. 30, 2025, entitled “METHODS AND APPARATUS FOR ADAPTIVE CHARGE NEUTRALIZATION USING AN ANTENNA MOUNTED TO AN ION EMITTER.” The entirety of U.S. patent application Ser. No. 63/689,209 is expressly incorporated herein by reference.

### FIELD OF THE DISCLOSURE

This disclosure relates generally to ionization, and more particularly, to methods and apparatus for adaptive charge neutralization using an antenna mounted to an ion emitter.

### BACKGROUND

Ion emitters of charge neutralizers generate and supply both positive ions and negative ions, or AC, into the surrounding air or gas media. To generate gas ions, the amplitude of the applied voltage must be high enough to produce a corona discharge between at least two electrodes arranged as an ionization cell. In the ionization cell, at least one electrode is an ion emitter and another one may be a reference electrode.

### SUMMARY

Methods and apparatus for adaptive charge neutralization using an antenna mounted to an ion emitter are disclosed, substantially as illustrated by and described in connection with at least one of the figures, as set forth more completely in the claims.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIGS. 1A-1C illustrate example ion emitters configured to control an ionization output based on balance voltage feedback over multiple lengths, in accordance with aspects of this disclosure.

FIG. 2 is a block diagram of an example implementation of the AC charge neutralization system of FIG. 1.

FIG. 3 illustrates an example antenna for providing feedback to the ion emitters of FIGS. 1A-1C, and antenna hangers to mount the antenna to a body of the ion emitters.

FIG. 4A is a more detailed depiction of a first example antenna hanger that may be used to implement the antenna hangers of FIG. 3.

FIG. 4B is a more detailed depiction of a second example antenna hanger that may be used to implement the antenna hangers of FIG. 3.

FIG. 5 is a more detailed depiction of the second example antenna hanger of FIG. 4B mounted to a body of an ion emitter.

The figures are not necessarily to scale. Wherever appropriate, similar or identical reference numerals are used to refer to similar or identical components.

### DETAILED DESCRIPTION

Ion emitters, or charge neutralizers, emit positive and/or negative ions, or AC ions, to discharge static electricity that may be present on a surface or substrate, such as in a manufacturing facility. Disclosed example methods and apparatus for charge neutralization can be used in cleanroom production environments, and are particularly useful for semiconductor chip manufacturing.

Conventional ion emitters may adjust a balance of positive ions to negative ions based on feedback from a remotely situated antenna or other feedback device. Conventional antennas are placed proximate to the target of the emitted ions. Placement of the feedback antenna, which is essentially static, proximate to the target can make cleaning of the areas around the antenna more difficult. For example, because clean room environments may be physically cleaned (e.g., wiped, mopped) at intervals, the antenna may present an obstacle to efficient cleaning of the areas proximate the antenna (e.g., quickly cleaning without damaging the antenna).

Disclosed example ion emitters, methods, and retrofit kits allow the antenna to be placed in a less intrusive position, while still providing sufficiently accurate balance feedback to allow for ion balances as low as +/−5 volts. Some disclosed ion emitters include one or more antenna hangers, which are supported by a body of the ion emitter and configured to position the antenna within an emission path of the emitter nozzles of the ion emitter. Compared with conventional antenna placement, disclosed example antenna hangers provide closer positioning of the antenna to the emitter nozzles, and position the antenna within the streams of ions emitted by the ion emitters. Accordingly, systems including disclosed antenna hangers are easier to clean, and reduce the risk of damage to the antenna during physical cleaning.

As used herein, “exceeding” a threshold voltage can occur in either the positive (e.g., more positive than the threshold) or negative (e.g., more negative than the threshold) directions.

As used herein, a “balance voltage” refers to a net voltage from ionization by the emitter.

The terms “ionization” and “charge neutralization” are used interchangeably in this document.

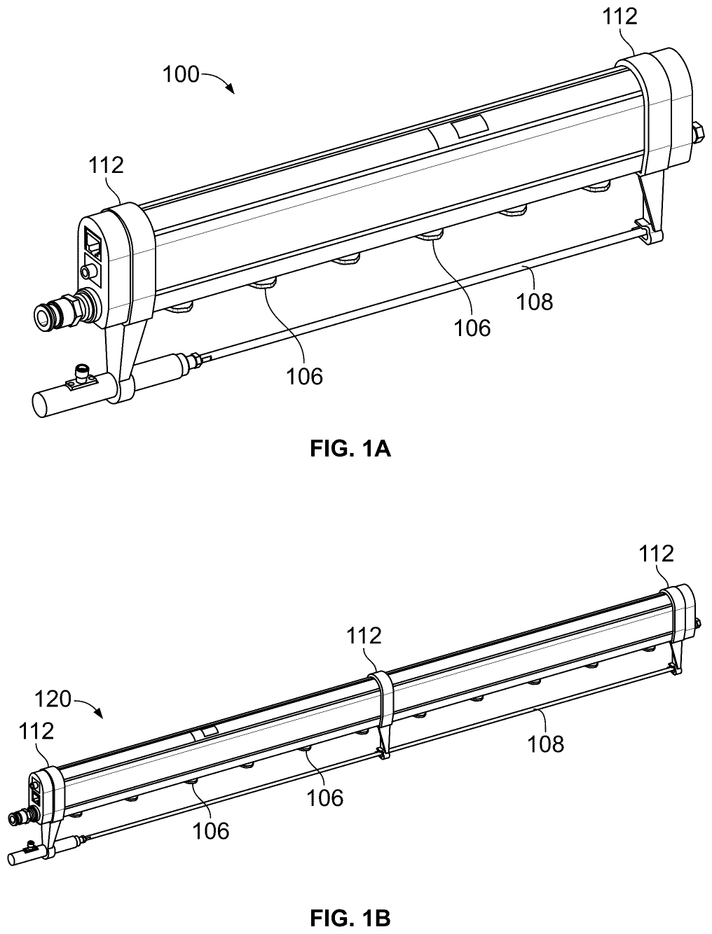

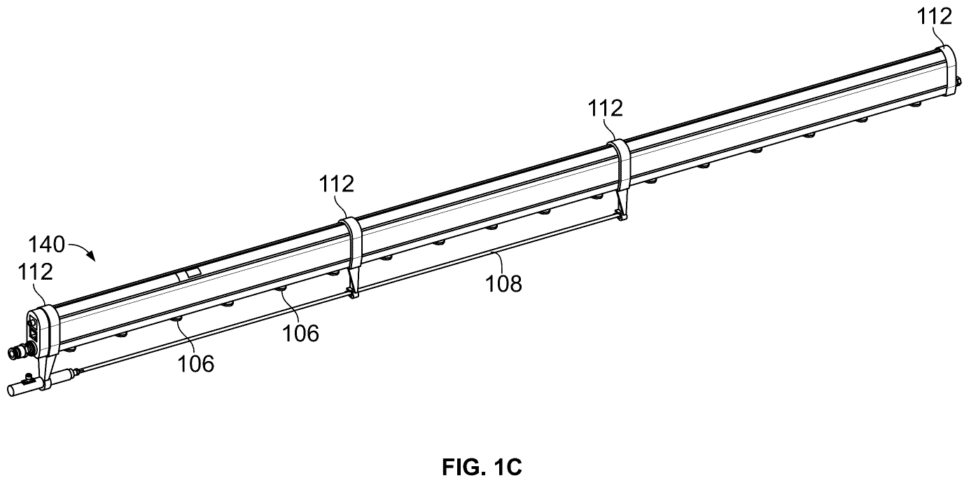

FIG. 1A illustrates an example AC charge neutralization ion emitter 100 configured to control an ionization output based on balance voltage feedback. The example ion emitter 100 outputs positive and negative ions to neutralize electric charges on a target device or substrate.

To generate the ions, the example ion emitter 100 includes one or more ion emitter nozzles 106, which are coupled to one or more power supplies that provide a high voltage, high frequency AC signal for generation of the ions. The ion emitter 100 may include any number of emitter nozzles 106 to disperse ions to a desired area or size of the target device or substrate. By alternating positive and negative ions, the example ion emitter 100 effectively neutralizes static charge present on the target device or substrate, while reducing or avoiding charging the target device or substrate with the ions.

The ion emitter 100 of FIG. 1 alternates positive and negative ions by controlling the output voltage at the nozzles 106 to output periods of positive ions and periods of negative ions. The relative durations of the positive period to the negative period may be controlled based on a desired balance. In contrast with conventional charge neutralization systems, the example ion emitter 100 achieves a balance voltage within +/−5V by measuring the balance voltage via an antenna 108 and adjusting the ion balance based on the measurements. For example, the ion emitter 100 may adjust the relative durations of positive ion periods and negative ion periods to adjust the output balance. The antenna 108 may be positioned within an emission path of the positive ions and negative ions such that the antenna 108 measures a balance voltage representative of the output of ion emitter 100. Using the feedback from the antenna 108, the ion emitter 100 repeatedly (e.g., constantly) adjusts the relative balance of positive and negative ion generation periods.

In the example of FIG. 1A, the antenna 108 is supported by (e.g., suspended from, attached to, etc.) a body 110 of the ion emitter 100 to locate the antenna 108 closer to the emitter nozzles 106 than in conventional ion emitters. As described in more detail below, the example antenna 108 is supported by one or more antenna hangers 112, which are supported by the body 110 and position the antenna 108 within the emission path(s) of the emitter nozzles 106.

FIG. 1B illustrates another example ion emitter 120 configured to control an ionization output based on balance voltage feedback. FIG. 1C illustrates yet another example ion emitter 140 configured to control an ionization output based on balance voltage feedback. The ion emitter 120 includes more nozzles 106 than the ion emitter 100, and the ion emitter 140 includes more nozzles 106 than both the ion emitters 100, 120. Each of the ion emitters 120, 140 includes a body 110, and the antenna 108 is supported by the body 110 of the respective ion emitter 120, 140.

In the examples of FIGS. 1A and 1B, the antenna 108 spans across the emission paths of all of the nozzles 106. In contrast, in the example of FIG. 1C, the antenna 108 spans across a number of the nozzles 106, but fewer than all of the nozzles.

In each of the example ion emitters 100, 120, 140, the antenna 108 measures the ion balance of ions emitted by the plurality of emitter nozzles 106. The antenna 108 provides a measurement signal to control circuitry that controls the power supply to output the positive and negative ions. By adjusting an emission duration for each of the positive ions and the negative ions, the control circuitry can control a balance of the ions emitted by the ion emitter 100, 120, 140.

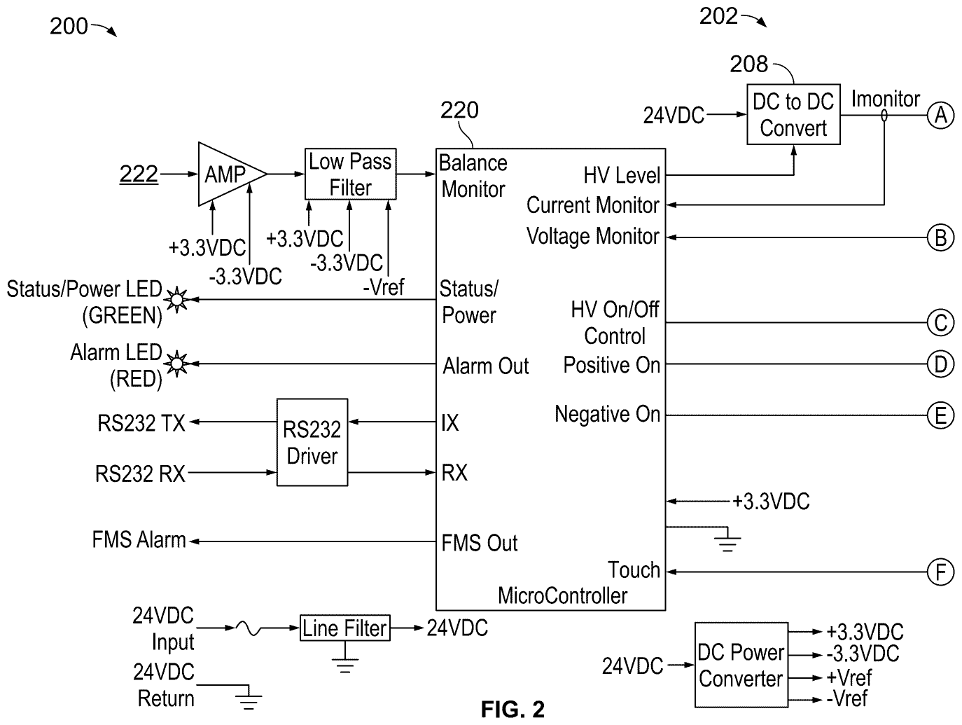

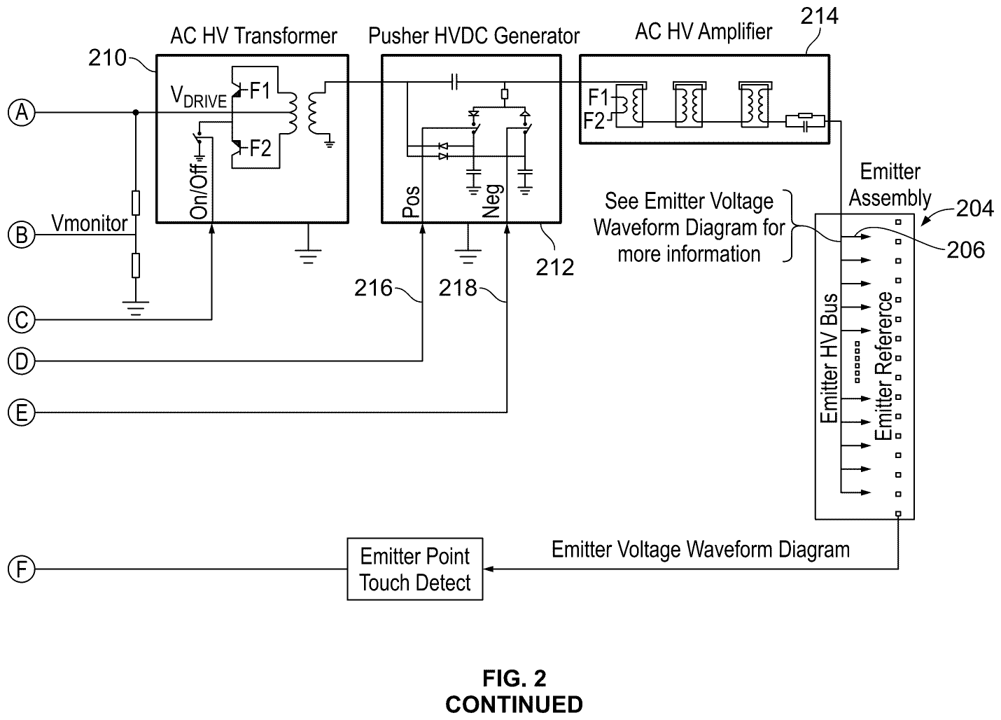

FIG. 2 is a block diagram of an example implementation of the AC charge neutralization ion emitter 100 of FIG. 1. The example of FIG. 2 includes an ion emitter 200 having a high voltage, high frequency (HVHF) power supply 202 which outputs an HVHF signal to an emitter assembly 204 having a number of emitters 206. In some examples, the emitters 206 are silicon-based or titanium-based. Based on the HVHF signal from the power supply 202, the emitters 206 create and output positive and negative ions.

The HVHF power supply 202 includes a DC-DC converter 208, an AC HV inverter 210, a DC offset generator 212, and an AC HV amplifier 214. The DC-DC converter 208 outputs a DC signal to the inverter 210, which generates an AC signal. The DC offset generator 212 selectively generates a DC offset signal based on polarity control signals 216, 218. If a positive polarity control signal 216 is active, the DC offset generator 212 generates a positive DC offset. Conversely, if a positive negative control signal 218 is active, the DC offset generator 212 generates a negative DC offset. If neither of the polarity control signals 216, 218 are active, the DC offset generator 212 does not generate a DC offset. The DC offset voltage, whether positive or negative, is combined with the AC signal output by the AC HV inverter 210 to generate a combined signal.

The AC HV amplifier 214 amplifies the voltage of the combined signal output by the DC offset generator 212.

The example ion emitter 200 includes control circuitry 220 to control the HVHF power supply 202. The example control circuitry 220 may include a general purpose microprocessor, a microcontroller, a system-on-a-chip (SoC), an application specific integrated circuit (ASIC), and/or any other type of digital and/or analog circuitry.

The control circuitry 220 includes at least one controller or processor that controls the operations of the ion emitter 200. The control circuitry 220 receives and processes multiple inputs associated with the performance and demands of the system. The control circuitry 220 may include one or more microprocessors, such as one or more “general-purpose” microprocessors, one or more special-purpose microprocessors and/or ASICS, and/or any other type of processing device. For example, the control circuitry 220 may include one or more digital signal processors (DSPs).

The example control circuitry 220 may include one or more storage device(s) and one or more memory device(s). Storage device(s) (e.g., nonvolatile storage) may include ROM, flash memory, a hard drive, and/or any other suitable optical, magnetic, and/or solid-state storage medium, and/or a combination thereof. The storage device stores data (e.g., ionization configuration data), instructions, and/or any other appropriate data. Memory device(s) may include a volatile memory, such as random access memory (RAM), and/or a nonvolatile memory, such as read-only memory (ROM). The memory device(s) and/or the storage device(s) may store a variety of information and may be used for various purposes. For example, the memory device(s) and/or the storage device(s) may store processor executable instructions (e.g., firmware or software) for the control circuitry 220 to execute.

The example control circuitry 220 outputs a target voltage level signal to the DC-DC converter 208 to control a DC output voltage to the AC HV inverter 210, and controls the polarity signals 216, 218 to the DC offset generator 212 to control the output. By controlling the polarity signals 216, 218, the example control circuitry 220 may control a balance of positive and negative ion output by the emitters 204.

The example control circuitry 220 further receives an balance voltage input 222 from a remote ion balance sensor, such as the antenna 108 of FIG. 1. The example control circuitry 220 may further include, or receive an input from, a balance detector which is connected to an antenna located near the ionization target. The balance detector may be implemented using a Simco-Ion™ Novx-based control system, such as the Novx 3352 Closed-loop Ionizer Controller or the Novx 3362 Closed-loop Ionizer Controller. In other examples, the control circuitry 220 or the ion emitter 200 may include the balance detector, which receives the feedback signal directly from the antenna 108.

The example control circuitry 220 may execute a PID controller, and/or other type of filter, to filter the balance voltage measurement received via the antenna 108. In some examples, the balance voltage input 222 is determined using an analog-to-digital converter (ADC) circuit configured to receive the input signal from the antenna 108, and the control circuitry 220 applies one or more filters and/or control loops to the balance voltage input 222 to adjust a balance value for controlling the polarity signals 216, 218. The control circuitry 220 receives the balance voltage input 222 at a regular interval, as often as the ADC or other circuit can sample and deliver the balance voltage input 222, in response to one or more event types, and/or at any other times.

A pressurized source of air, nitrogen, or argon may be connected to the ion emitter 200 via an inlet to create an air flow or gas flow. In other examples, the emitter assembly 204 may permit flow of ambient air to carry the ions toward the output of the emitter assembly 204. When present, the air flow or gas flow entrains positive and negative ions and carries the ions through an ionizer outlet toward a target.

Example implementations of the ion emitter 100 are disclosed in U.S. Pat. No. 11,843,225 (Heymann, et al.), entitled “Methods and apparatus for adaptive charge neutralization.” The entirety of U.S. Pat. No. 11,843,225 is incorporated herein by reference.

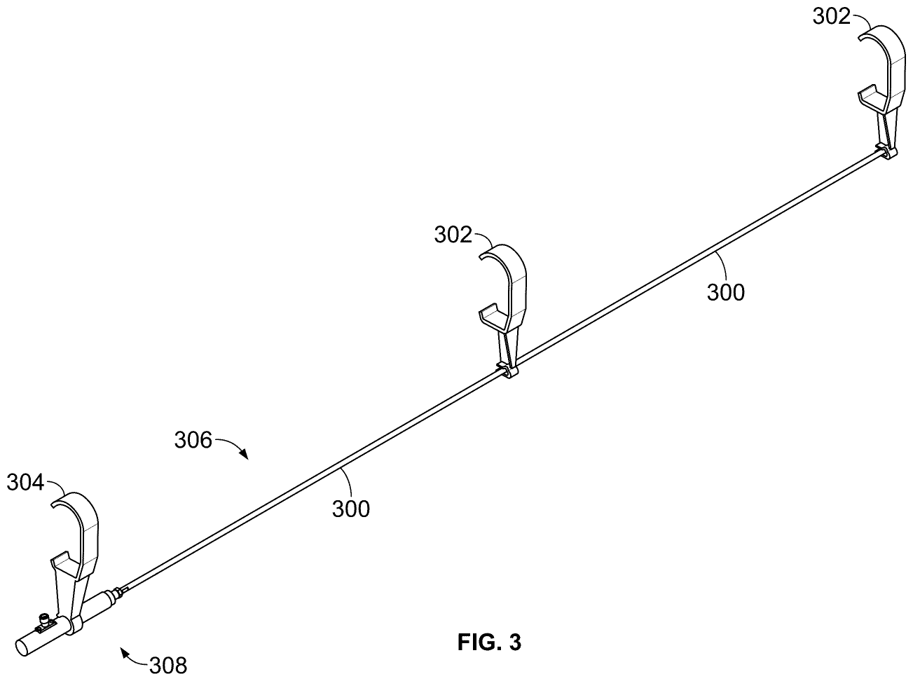

FIG. 3 illustrates an example antenna 300 for providing feedback to the ion emitters 100, 120, 140 of FIGS. 1A-1C, and antenna hangers 302, 304 to mount the antenna 300 to the body 110 of the ion emitter 100, 120, 140. In the example of FIG. 3, the number of antenna hangers 302, 304 is selected to provide sufficient support and rigidity to the antenna 108 to maintain a substantially consistent distance between the antenna 108 and the body 110 of the ion emitter 100, 120, 140 along a length of the antenna 108. Accordingly, while three example antenna hangers 302, 304 are illustrated in FIG. 3, more antenna hangers 302, 304 may be used for a less rigid type of antenna and/or fewer hangers 302, 304 may be used for a more rigid antenna.

The example antenna hangers 302, 304 and the antenna 300 may be provided with the ion emitter 100, 120, 140, and/or may be provided as a retrofit kit for repositioning the antenna of a conventional ion emitter.

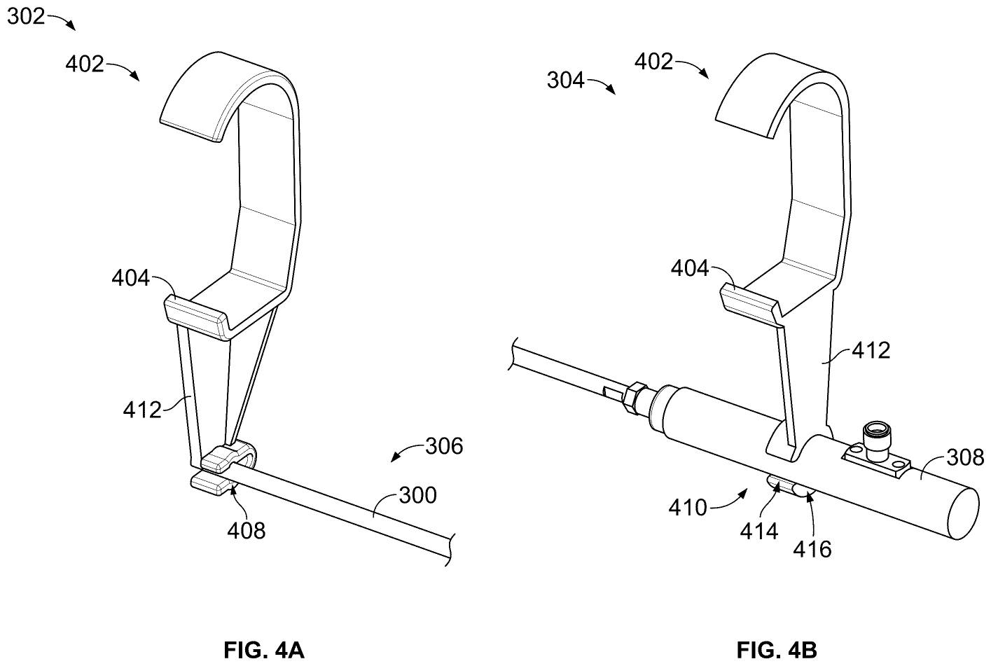

The example antenna hangers 302 are a first type of hanger that holds a rod portion 306 of the antenna 300 that has a smaller cross section. FIG. 4A is a more detailed depiction of the example first type of antenna hanger 302. The example antenna hanger 304 is a second type of hanger that holds a stem portion 308 of the antenna 300 has a larger cross section. FIG. 4B is a more detailed depiction of the second type of antenna hanger 304.

Each of the example antenna hangers 302, 304 includes a hook portion 402 configured to removably clip onto the body 110 of the ion emitter 100, 120, 140. For example, the hook portion 402 may slightly deflect when placed onto the body 110, and a clasp surface 404 extends around the body 110 to hold the antenna hanger 302, 304 in place on the body 110. The antenna hanger 302, 304 may be removed from the body 110 by pushing on the clasp surface 404 to deflect the hook portion 402 and release the clasp surface from the body 110.

The hook portions 402 of the antenna hangers 302, 304 may be modified for different body shapes of the ion emitters 100, 120, 140, such as to adequately retain the antenna hangers 302, 304 on the body 110 of the ion emitters 100, 120, 140 while allowing the antenna hangers 302, 304 to be quickly attached and detached (e.g., for cleaning of the antenna 300, antenna hangers 302, 304, and/or the body 110 of the ion emitters 100, 120, 140).

Each of the antenna hangers 302, 304 also includes a spring clip portion 406 to retain the antenna 300. The example first type of antenna hanger 302 includes a first type of spring clip 406 which has a C-shape. The example first type of spring clip 406 is dimensioned to grasp the rod portion 306 of the antenna 300. The spring clip 406 may be deflected to expand the opening of the spring clip 406 to insert or remove the antenna 300, and may further include a wider retention portion 408. When the antenna 300 is inserted into the wider retention portion 408, the spring clip 406 is allowed to relax to close the opening in the spring clip 406 and retain the antenna 300.

The example second type of spring clip 410 has a C-shape, with a smaller opening portion 414 and a wider retention portion 416. The example second type of spring clip 410 is dimensioned to grasp the stem portion 308 of the antenna 300. The spring clip 410 may be deflected to expand the opening of the spring clip 410 to insert or remove the stem portion 308. When the stem portion 308 is inserted into the retention portion 416, the spring clip 410 is allowed to relax to close the opening in the spring clip 410 and retain the antenna 300.

In other examples, the stem portion 308 may be held by the first type of spring clip 406 dimensioned for the stem portion 308 and/or the rod portion 306 may be held by the second type of spring clip 410 dimensioned for the rod portion 306.

The example antenna hangers 302, 304, the hook portions 402, and/or the spring clips 406, 410 may be constructed from an insulating material, such as an insulating plastic. In other examples, all or a portion of the antenna hangers 302, 304, the hook portions 402, and/or the spring clips 406, 410 may be constructed using a conductive or partially conductive material, and include an insulating material such as an insulating lining to insulate the antenna 300 from the body 110 of the ion emitter 100, 120, 140.

The hook portion 402 and the spring clip portion 406 are connected by an extension 412. The extension 412 is a structural component that rigidly supports the spring clip portion 406 in a position with respect to the hook portion 402. The distance between the hook portion 402 and the spring clip portion 406 may be selected based on a desired distance from the antenna 300 to the emitter nozzles 106. For example, the distance between the hook portion 402 and the spring clip portion 406 positions the antenna 108 between 0.5 inches and 6 inches from the emitter nozzles 106 within an emission path of the nozzles 106. In some examples, the distance between the hook portion 402 and the spring clip portion 406 positions the antenna 108 between 0.5 inches and 3 inches from the emitter nozzles 106 within an emission path of the nozzles 106. In some examples, the antenna hangers 302, 304 position the antenna 108 in alignment with the centers of the emitter nozzles 106. In other examples, the antenna hangers 302, 304 position the antenna 108 out of alignment with the centers of the emitter nozzles 106, but within the emission paths (e.g., cones of emission) of the emitter nozzles 106. In some examples, the extension 412 may be constructed to have an adjustable distance between the hook portion 402 and the spring clip portion 406, and/or an adjustable alignment with respect to the emitter nozzles 106.

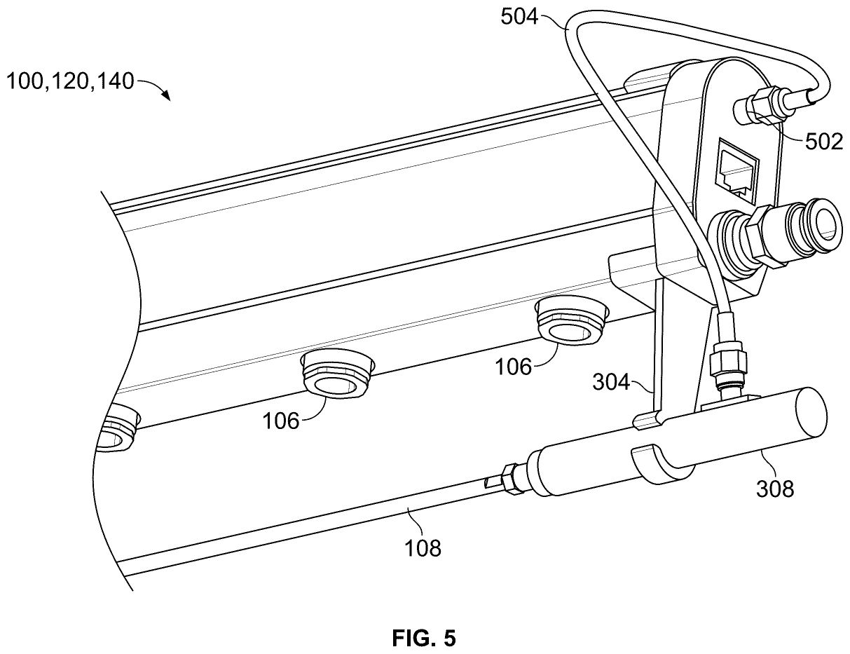

FIG. 5 is a more detailed depiction of the second type of antenna hanger 304 of FIG. 4B mounted to a body 110 of an ion emitter 100, 120, 140. As illustrated in FIG. 5, the stem portion 308 of the antenna 300 may be connected to an antenna port 502 (e.g., the balance voltage input 222 of FIG. 2) of the ion emitter 100, 120, 140 via an antenna cable 504, to provide the balance voltage feedback. By positioning the antenna 108 close to the body 110 of the ion emitter 100, 120, 140, the antenna hangers 302, 304 provide the additional benefit of shortening the length of the antenna cable 504 relative to conventional ion emitter feedback systems.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. For example, block and/or components of disclosed examples may be combined, divided, re-arranged, and/or otherwise modified. In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

What is claimed is:

1. A ion emitter, comprising:
a body;
a plurality of emitter nozzles on the body;
a power supply configured to supply a high frequency alternating current (AC) signal to the plurality of emitter nozzles;
an antenna configured to measure an ion balance of ions emitted by the plurality of emitter nozzles;
control circuitry configured to control the power supply based on the ion balance measured via the antenna; and
an antenna hanger supported by the body and configured to position the antenna within an emission path of the plurality of emitter nozzles.

2. The ion emitter as defined in claim 1, wherein the antenna hanger comprises a hook configured to removably clip onto the body.

3. The ion emitter as defined in claim 1, wherein the antenna hanger comprises a spring clip configured to retain the antenna.

4. The ion emitter as defined in claim 3, wherein the spring clip comprises an insulating material.

5. The ion emitter as defined in claim 1, wherein the antenna hanger is an insulating material.

6. The ion emitter as defined in claim 1, wherein the antenna hanger is configured to position the antenna between 0.5-6 inches from the plurality of emitter nozzles.

7. The ion emitter as defined in claim 6, wherein the antenna hanger is configured to position the antenna between 0.5-3 inches from the plurality of emitter nozzles.

8. The ion emitter as defined in claim 1, wherein the antenna hanger is configured to position the antenna in alignment with the centers of the plurality of emitter nozzles.

9. The ion emitter as defined in claim 1, wherein the antenna hanger is configured to position the antenna off-center from the plurality of emitter nozzles and within cones of emission of the plurality of emitter nozzles.

10. The ion emitter as defined in claim 1, wherein the antenna is a rod antenna.

11. A retrofit kit for an ion emitter, the retrofit kit comprising:
a plurality of antenna hangers configured to grasp a body of the ion emitter and to position an antenna within an emission path of a plurality of emitter nozzles of the ion emitter.

12. The retrofit kit of claim 11, further comprising the antenna configured to be held by the plurality of antenna hangers and to output a signal to a balance voltage input of the ion emitter.

13. The retrofit kit of claim 11, wherein the plurality of antenna hangers comprise hooks configured to removably clip onto the body.

14. The retrofit kit of claim 11, wherein the plurality of antenna hangers comprise spring clips configured to retain the antenna.

15. The retrofit kit of claim 14, wherein the spring clips comprise an insulating material.

16. The retrofit kit of claim 11, wherein the plurality of antenna hangers comprise an insulating material.

17. The retrofit kit of claim 11, wherein the plurality of antenna hangers are configured to position the antenna between 0.5-6 inches from the plurality of emitter nozzles.

18. The retrofit kit of claim 17, wherein the plurality of antenna hangers are configured to position the antenna between 0.5-6 inches from the plurality of emitter nozzles.

19. The retrofit kit of claim 11, wherein the plurality of antenna hangers are configured to position the antenna in alignment with the centers of the plurality of emitter nozzles.

20. The retrofit kit of claim 11, wherein the plurality of antenna hangers are configured to position the antenna off-center from the plurality of emitter nozzles and within cones of emission of the plurality of emitter nozzles.
